(19) United States
(12) Patent Application Publication
(10) Pub. No.: US 2024/0213989 A1
(43) Pub. Date: Jun. 27, 2024

(54) System and method for testing a phase noise or jitter of a phase-locked loop

(71) Applicant: Intel Corporation, Santa Clara, CA (US)

(72) Inventors: Marc Jan Georges TIEBOUT, Finkenstein (AT); Edwin THALLER, Faak am See (AT); Kameran AZADET, San Ramon, CA (US)

(21) Appl. No.: 18/145,867

(22) Filed: Dec. 23, 2022

(51) Int. Cl. H03L 7/091; H03L 7/07; H03L 7/099

(52) U.S. Cl. CPC H03L 7/091; H03L 7/07; H03L 7/0991

(57) ABSTRACT

A system and method for testing or determining a phase noise and/or jitter of a phase locked loop (PLL). The system includes a first PLL configured to generate a first clock signal based on a reference clock signal, a first buffer for providing the reference clock signal to the first PLL, a mixer configured to mix the first clock signal with a second clock signal, an analog-to-digital converter (ADC) configured to convert an output of the mixer to digital data, and a processing circuit configured to process the digital data to determine a phase noise or jitter of the first PLL and generate an output indicative of the phase noise or jitter of the first PLL. The system may include a second PLL configured to generate the second clock signal based on the reference clock signal, and a second buffer for providing the reference clock signal to the second PLL.

### BACKGROUND

Electrical system such as communication and RADAR systems require low phase noise clocks serving as a local oscillator signal for up/down-conversion, as analog-to-digital converter (ADC) and digital-to-analog converter (DAC) clocks, and/or high-speed data interfaces. Phase noise or jitter is a crucial parameter for system performance and needs to be guaranteed in mass production and preferably over a guaranteed lifetime.

### BRIEF DESCRIPTION OF THE FIGURES

Some examples of apparatuses and/or methods will be described in the following by way of example only, and with reference to the accompanying figures, in which

FIG. 1 shows an exemplary PLL phase noise measurement macro for testing a PLL;

FIG. 2 shows an exemplary radio frequency (RF) transmitter based on an all-digital PLL frequency synthesizer;

FIG. 3 shows a system configured for testing a phase noise and/or jitter of a PLL in accordance with one example;

FIG. 4 shows an example system that may operate either in a normal mode or a phase noise/jitter test mode;

FIG. 5 shows a system configured for testing a PLL phase noise and/or jitter of a PLL in accordance with another example;

FIG. 6 is an example mixer;

FIG. 7 is a block diagram of an example transceiver device in which the examples disclosed herein may be implemented;

FIG. 8 is a flow diagram of an example process of testing phase noise and/or jitter of a PLL;

FIG. 9 illustrates a user device in which the examples disclosed herein may be implemented; and

FIG. 10 illustrates a base station or infrastructure equipment radio head in which the examples disclosed herein may be implemented.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

Conventionally, devices (e.g., a transceiver integrated circuit (IC) chip, etc.) are tested for phase noise or jitter during production at the factory. Each device may be tested using an automated test equipment (ATE). An ATE is an equipment that performs tests on a device using automation to quickly perform measurements and evaluate the test results. The ATE tests and diagnoses faults in the devices and the devices with faults may be discarded at factory testing. The device testing requires a high-end ATE, which can incur excessive costs. Ultra-low phase noise measurements require long testing times, which can be a prohibitively long period for mass production of the devices. In addition, the phase noise performance of the best-in-class phase-locked loop (PLL) may be below the noise floor of today's ATE equipment and aging effects are not covered at all.

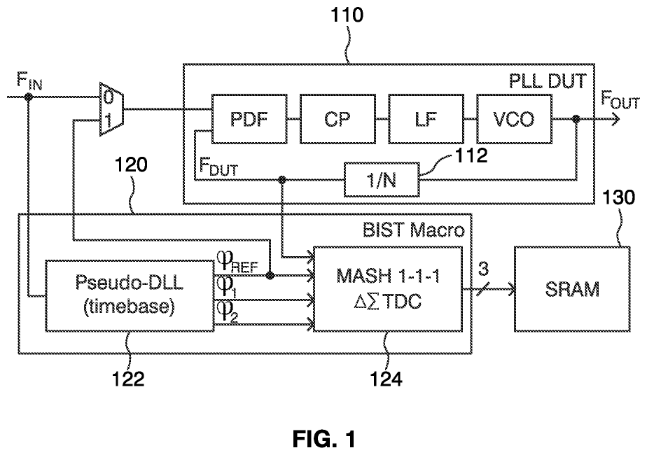

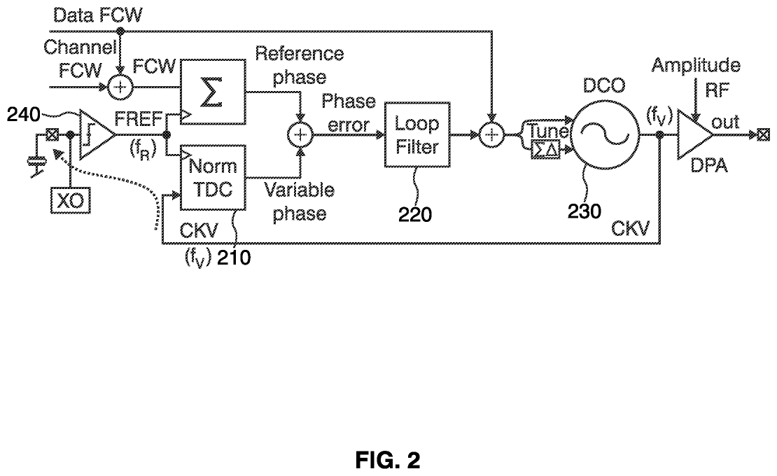

A phase noise built-in self-test (BIST) has been integrated into the device to detect the faults in the devices. FIGS. 1 and 2 show a conventional BIST for analog PLL and all-digital PLL, respectively. FIG. 1 shows a PLL phase noise measurement (BIST) macro for testing a PLL 110 based on a phase-frequency detector/charge pump (PFD/CP) MASH 1-1-1 ΔΣ time-to-digital converter (TDC). The BIST macro 120 in FIG. 1 measures the post-divider feedback clock (the PLL output clock (Fₒᵤₜ) divided by the divider 112) of the integrated PLL 110. The BIST macro 120 includes a pseudo-delay-locked loop (DLL) 122 and a third-order MASH 1-1-1 ΔΣTDC 124 to characterize the PLL jitter. The TDC digital output is stored in the static random-access memory (SRAM) 130 for post-processing analysis.

FIG. 2 shows a radio frequency (RF) transmitter based on an all-digital PLL (ADPLL) frequency synthesizer. In FIG. 2, a TDC 210 is augmented with a normalizing multiplier that produces a fixed-point variable phase, which is then subtracted from the reference phase to produce the digital phase error. The phase error is then filtered by a digital loop filter 220 and then normalized by the digitally controlled oscillator (DCO) gain to correct the phase/frequency of the DCO 230 in negative feedback.

The general principle of implementing integrated phase noise measurement in conventional schemes is to use the statistics of the TDC outputs and calculate a phase noise or jitter out of the digital output stream. In case of an analog PLL or bang-bang all-digital PLL (ADPLL), a TDC needs to be included. The conventional scheme in FIG. 1 skips the contribution of the analog input buffer providing the reference signal (F_{IN}). In case of an all-digital PLL shown in FIG. 2, a TDC is typically already included, and a phase noise measurement capability may be achieved just by collecting the statistics. However, the contribution of the analog input buffer 240 providing the reference signal (FREF) is not included in the phase noise measurement.

Examples of a system for testing/determining a phase noise or jitter of a PLL (i.e., a frequency synthesizer) will be explained hereafter. In examples, a pair of identical phase-coherent PLLs are used for the phase noise/jitter test. Each PLL includes its own complete clock reference path, and the two PLLs may receive the same reference clock signal and generate a respective clock signal based on the same reference clock signal. The outputs of the pair of PLLs are then mixed by a mixer (analog mixer) and the mixer output is converted to digital data by an ADC. Digital post processing is then performed on the mixer output in a digital domain to determine the phase noise and/or jitter. The mixing of the two PLL outputs (any pair of PLLs among a plurality of PLLs in the device under test) results in summed phase noise of the pair of PLLs around direct current (DC). Fast Fourier transform (FFT) of the mixer output provides phase noise versus frequency, and integration of the phase noise provides an integrated jitter.

In some examples, a PLL output (an output of a single PLL in the device under test) may be mixed with an external clock signal (a clock signal from an external PLL) and the mixer output is converted to a digital domain and then processed by a digital post-processor to determine the phase noise and/or jitter. The external clock signal may be a highly accurate clock signal.

In examples, the reference buffer phase noise contribution is included in determining the phase noise or jitter of a PLL. In addition, aging effects on the PLL can also be covered in determining the phase noise or jitter. The phase noise BIST measurement can be executed at any time, e.g., at each device/chip boot. The examples do not need expensive ATE equipment for testing the phase noise or jitter.

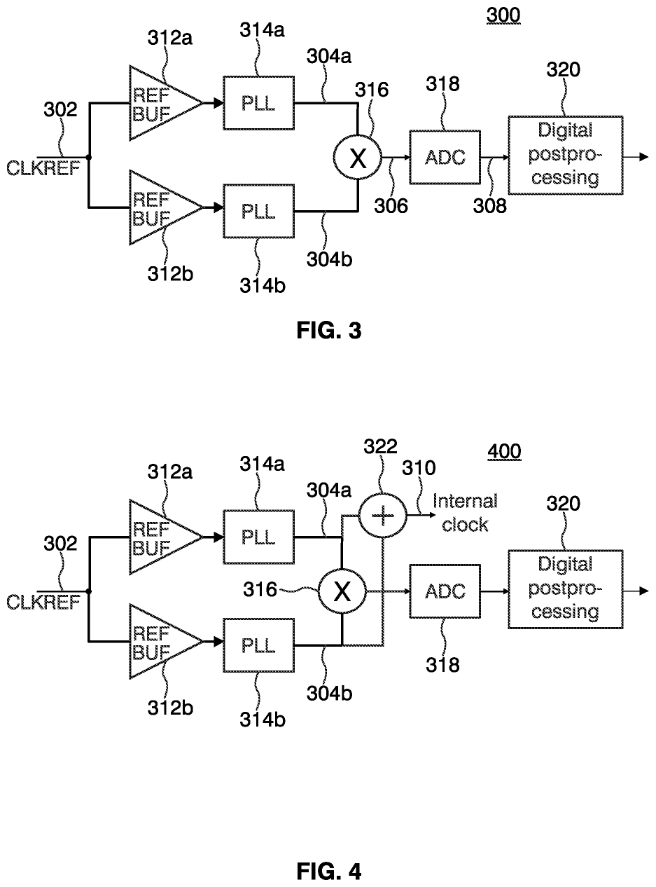

The system disclosed herein with respect to FIGS. 3-5 may be included in, or implemented for, a transceiver device/IC chip or any device/IC chip including a PLL (frequency synthesizer). The system may be included in a user equipment (e.g., a mobile phone, a tablet computer, a laptop computer, etc.), a base station (e.g., eNB, gNB, a WLAN access points, etc.) or other wireless devices configured to transmit and receive data in accordance with any suitable wireless communication protocol and/or data rates.

FIG. 3 shows a system configured for testing and/or determining a phase noise and/or jitter of a PLL in accordance with one example. The system 300 includes PLLs 314a, 314b, buffers 312a, 312b, a mixer 316, an ADC 318, and a processor 320. It should be noted that FIG. 3 shows only two PLLs 314a and 314b as an example, not as a limitation, and the system 300 may include more than two PLLs and any two PLLs among a plurality of PLLs in the device under test may be paired for testing the PLL phase noise and/or jitter as shown in FIG. 3.

The two PLLs 314a, 314b may be identical phase-coherent PLLs. A PLL (frequency synthesizer) is a system that generates an output signal whose phase is related to the input reference signal. The PLLs 314a, 314b may be any conventional PLL, either a digital PLL or an analog PLL. Each PLL 314a, 314b includes its own complete clock reference path. Each PLL 314a, 314b may receive the same reference clock signal 302 via a separate identical buffer 312a, 312b as shown in FIG. 3. PLL 314a receives the reference clock signal 302 via a buffer 312a and PLL 314b receives the same reference clock signal 302 via a buffer 312b. Both PLLs 314a, 314b generate a respective clock signal 304a, 304b based on the same reference clock signal 302.

The clock signals 304a, 304b generated by the pair of PLLs 314a, 314b are mixed by a mixer 316 (analog mixer). A mixer (i.e., a frequency mixer) is a device that generates new frequencies from the input signals applied to the mixer. The mixer generates new signals at the sum and difference of the input frequencies. The mixing of the clock signals 304a, 304b output from the two PLLs 314a, 314b (in general, any pair of PLLs among a plurality of PLLs) results in summed phase noise of the pair of PLLs 314a, 314b around DC (difference of identical input frequencies). In this example, the phase noise/jitter of each PLL is measured against the other PLL.

The mixer output 306 may be filtered by a low pass filter (not shown in FIG. 3) and then converted to digital data 308 by an ADC 318. The processor 320 then performs digital post-processing on the digital data 308 in digital domain to determine the phase noise or jitter of the PLLs 314a, 314b.

The phase noise may be determined by spectrum analysis. Phase noise is defined as the ratio of the noise in a 1-Hz bandwidth at a specified frequency offset to the clock signal amplitude at the oscillator frequency. Jitter may be determined by integrating the phase noise power over the offset frequency range of interest. The processor 320 may perform fast Fourier transform (FFT) on the mixer output to determine the phase noise versus frequency. The processor 320 may integrate the phase noise power over a frequency range to determine an integrated jitter. The processor 320 may then output a signal indicative of, or generated based on, the measured phase noise and/or jitter The FFT of the ADC output directly provides the phase noise of the sum of both PLLs.

The phase noise and/or jitter measurement processing (e.g., the mixing of the two PLL outputs, ADC conversion, and/or digital post-processing) may be performed in backend or frontend test (e.g., at factory test). The example scheme disclosed herein can solve the ATE testing issues as to the noise floor or excessive costs for the testing equipment. The device may be tested at factory and may then be discarded or accepted based on the PLL phase noise/jitter test.

Alternatively, the system 300 may be integrated into a device as a BIST module and the phase noise and/or jitter measurement processing (e.g., the mixing of the two PLL outputs, ADC conversion, and digital post-processing) may be performed anytime (e.g., at boot time of the device). The PLL phase noise/jitter measurement may be programmed to be performed at any time (e.g., at boot time of the device) and an appropriate measure (e.g., disabling certain functionalities or a portion of the circuitry that is affected by the PLL having a phase noise or jitter above a certain threshold, etc.) may be performed based on the PLL phase noise/jitter self-test.

In the example shown in FIG. 3, two (or more) identical phase-coherent PLLs are included in the device and used for testing. Using two or more identical phase-coherent PLLs requires an area on a device/IC chip, especially for all-digital PLLs. However, the area penalty may be moderate since high performance IC devices use a dual core or quad core DCO, which dominates the area. The area penalty building two ADPLLs around two DCO cores is much smaller than doubling the PLL area.

FIG. 4 shows an example system that may operate either in a normal mode or a phase noise/jitter test mode. The system 400 is configured for testing a phase noise and/or jitter of a PLL as explained above. The system 400 is same as the system 300 shown in FIG. 3, and therefore the same components will not be explained again for simplicity. The system 400 further includes a combiner 322 for combining the two clock signals 304a, 304b generated by the two PLLs 314a, 314b (or n clock signals generated by n PLLs in general). The system 400 may operate in a normal mode or a phase noise/jitter test mode. During the phase noise/jitter test mode, the clock signals 304a, 304b from the two PLLs 314a, 314b are mixed and a phase noise/jitter of each PLL is measured against the other PLL as explained above with respect to FIG. 3. During the normal mode, the clock signals 304a, 304b of the two PLLs 314a, 314b (or n PLLs in general), are not mixed but may be summed/averaged by the combiner 322. Signal averaging is a technique applied in time domain to increase the strength of a signal relative to noise. By averaging a set of replicate signals, the signal-to-noise ratio (SNR) can be increased, in proportion to the square root of the number of signals. By summing/averaging n PLL clock signals, the phase noise can be improved by 10×log(n). The summed/averaged clock signal 310 may then be used as an internal clock signal for the device (e.g., as ADC or DAC clock signal).

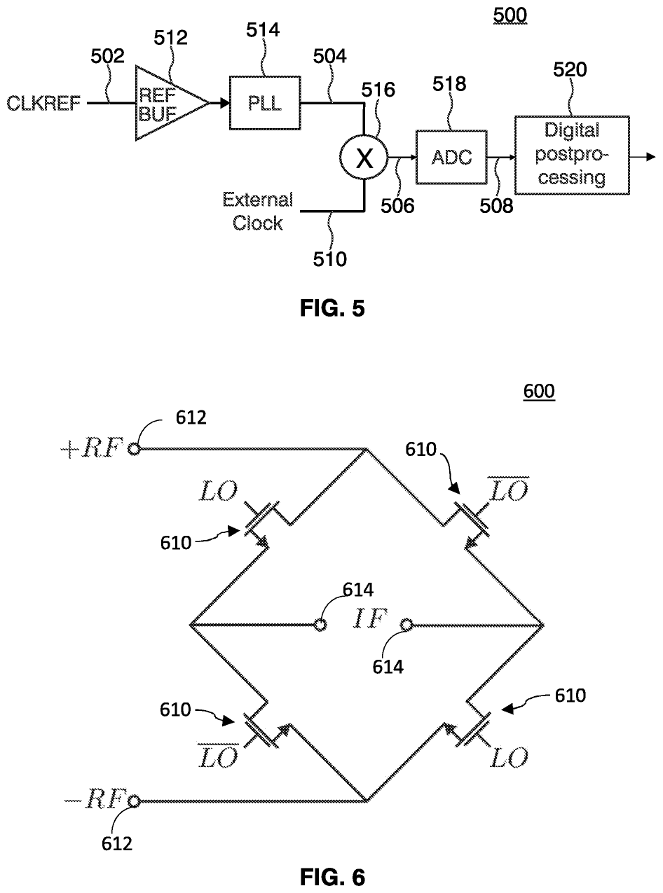

FIG. 5 shows a system configured for determining and/or testing a PLL phase noise and/or jitter of a PLL in accordance with another example. In this example, a PLL output (a clock signal generated by a single PLL 514) is mixed with an external clock signal 510 (a clock signal from an external signal source) that has a phase noise well below the phase noise level of PLL 514. The system 500 includes a PLL 514, a buffer 512, a mixer 516, an ADC 518, and a processor 520. FIG. 5 may include one PLL 514, but the system 500 may include more than one PLL and any one of the PLLs in the device may undergo a process for testing for the PLL phase noise and/or jitter as shown in FIG. 5, or for determining as to whether the PLL phase noise and/or jitter as shown in FIG. 5 would meet the predetermined value or threshold for example for production test or built-in self test, etc. The PLL 514 may be any PLL, either a digital PLL and/or an analog PLL. The PLL 514 receives the reference clock signal 502 via a buffer 512 and generates a clock signal 504 based on the reference clock signal 502. The clock signal 504 generated by the PLL 514 is mixed by a mixer 516 with an external clock signal 510. The external clock signal 510 may be a highly accurate RF clock signal. The mixer 516 generates new signals at the sum and difference of the two input frequencies. The mixing of the clock signal 504 and the external clock signal 510 results in summed phase noise of the two clock signals at certain frequency depending on the frequency of the two clock signals 504 and 510. The mixer output 506 may be filtered by a low pass filter (not shown in FIG. 5) and then converted to digital data 508 by an ADC 518. The processor 520 then performs digital post processing on the digital data 508 in digital domain to determine the phase noise or jitter of the PLL 514. In this example, the phase noise/jitter of the clock signal 504 of the PLL 514 is measured against the high-precision external clock signal 510.

As explained above, the processor 520 may perform spectrum analysis to determine the phase noise of the PLL 514. Phase noise is defined as the ratio of the noise in a 1-Hz bandwidth at a specified frequency offset to the clock signal amplitude at the oscillator frequency. Jitter may be determined by integrating the phase noise power over the frequency range of interest. The processor 520 may perform fast Fourier transform (FFT) on the mixer output to determine the phase noise versus frequency. The processor 520 may integrate the phase noise power over a frequency range to determine an integrated jitter. The processor 520 may then output a signal indicative of, or generated based on, the measured phase noise and/or jitter.

FIG. 6 is an example mixer that may be used in the systems 300, 400, 500 shown in FIGS. 3-5. The mixer 600 (mixer core) includes four transistors 610 coupled in a ring as shown in FIG. 6. The mixer 600 receives a differential input signal at terminals 612 and provides a differential output signal at terminals 614, or vice versa. The input signal and the output signal may be either an RF signal or an intermediate frequency (IF) signal depending on whether the mixer 600 is operating as an up-converter or a down-converter. Complementary local oscillator (LO) signals (LO and L̅O̅) are applied to the gate terminal of the transistors 610 as shown in FIG. 6. The mixer is controlled by adjusting the local oscillator bias voltage (i.e., the gate bias voltage) that is applied to the gate terminal of the transistors 610. For example, the operating point of the mixer 600 may be controlled by adjusting the LO bias voltage relative to the threshold voltage of the transistors 610. It should be noted that the mixer shown in FIG. 6 is merely one example, and any conventional mixer may be used in the systems 300, 400, 500 disclosed above.

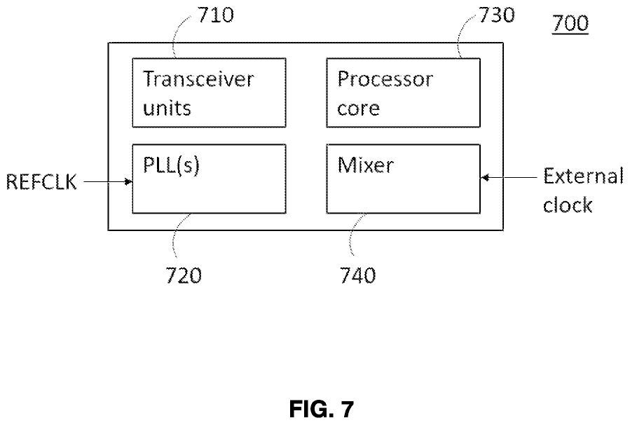

FIG. 7 is a block diagram of an example transceiver device in which the examples disclosed herein may be implemented. The transceiver device 700 (e.g., a transceiver integrated circuit (IC) chip) may include a plurality of transceiver units (TRXs) 710, one or more PLLs 720 including a buffer(s) for the reference clock for the PLL(s), a processor core(s) 730, and a mixer 740, etc. Each transceiver unit (TRX) 710 may include an ADC and a DAC, etc. The transceiver device 700 may be included in any suitable type of device that transmits and receives wireless communication data. In some illustrative and non-limiting examples, the transceiver device 700 may be included in a user equipment (e.g., a mobile phone, a tablet computer, a laptop computer, etc.), a base station (e.g., eNB, gNB, a WLAN access points, etc.) or other wireless devices configured to transmit and receive data in accordance with any suitable wireless communication protocol and/or data rates.

In one example, the system 300, 400, 500 shown in FIGS. 3-5 may be included as a built-in self-test (BIST) module in the transceiver device 700 or any other electronic device that includes a PLL. The transceiver device 700 includes a terminal for receiving the reference clock signal (CLKREF) for the PLL(s) 720 and a routing channel for routing the reference clock signal to the PLL(s) 720 so that the PLL(s) 720 generate a clock signal based on the reference clock signal. In case where the transceiver device 700 includes two or more PLLs, the reference clock signal may be routed to the two or more PLLs via the routing channel so that the PLLs generate clock signals based on the same reference clock signal. The output(s) of the PLL or PLLs is/are routed to the mixer 740 (the on-chip mixer on the transceiver device) for mixing. In case of two-PLL testing, the clock signals generated by the two PLLs are routed to the mixer 740 for mixing as disclosed above. In case of single-PLL testing, the clock signal of the PLL is routed to the mixer 740 for mixing with an external clock signal. The mixer output may be converted to digital domain using any one of the ADCs in the transceiver device 700. The main ADC in the transceiver device 700 may be reused for the PLL testing. The mixer output in digital domain is processed by the processor core 730 in the transceiver device 700. The transceiver device 700 may have sufficient processing capability for the post-processing of the mixer output in digital domain to test/measure the phase noise and/or jitter of the PLL(s) 720. The system 300, 400, 500 integrated into the transceiver device 700 may operate as a fully functional BIST within the transceiver device 700. In this example, the PLL phase noise/jitter testing may be performed at anytime, for example at boot time of the transceiver device 700.

Alternatively, the transceiver device 700 may output the mixer output signal, or the digital data for backend/frontend production testing. The mixer output signal, or the digital data may be output from the transceiver device 700, and the processing for determining the phase noise and/or jitter may be performed using an external equipment (e.g., at factory production testing). This scheme could save costs or improve noise floor of measurement capability.

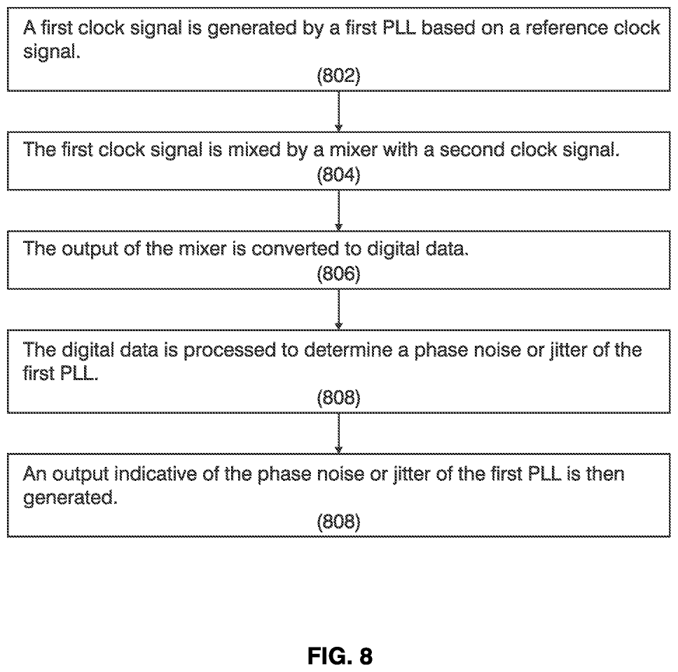

FIG. 8 is a flow diagram of an example process of testing/determining phase noise and/or jitter of a PLL. A first clock signal is generated by a first PLL based on a reference clock signal (802). The first clock signal is mixed by a mixer with a second clock signal (804). The second clock signal may be generated by a second PLL included in the system or may be originated from an external clock source. The output of the mixer is converted to digital data (806). The digital data is processed to determine a phase noise or jitter of the first PLL (808). An output indicative of, or generated based on, the phase noise or jitter of the first PLL is then generated (810). The method may further include generating, by a second PLL, the second clock signal based on the reference clock signal. Alternatively, the second clock signal may be received from an external clock source. The external clock source may be a high precision clock having a phase noise or jitter below a certain threshold. The method may also include combining the first clock signal and the second clock signal to generate a third clock signal. The third clock signal may be used as an internal clock signal for the device (such as an ADC or DAC clock signal). FFT processing may be performed on the digital data to perform spectrum analysis on the digital data to determine the phase noise. A phase noise power may be integrated over an offset frequency range of interest to determine the jitter.

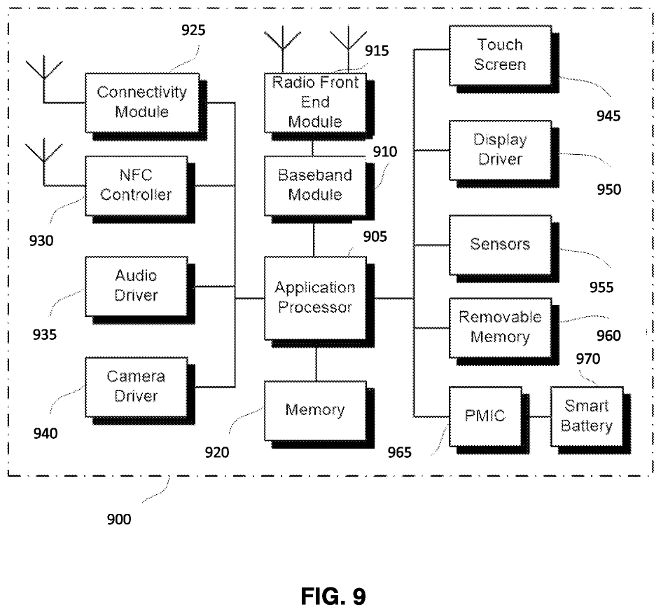

FIG. 9 illustrates a user device 900 in which the examples disclosed herein may be implemented. For example, the examples disclosed herein may be implemented in the radio front-end module 915, in the baseband module 910, etc. The user device 900 may be a mobile device in some aspects and includes an application processor 905, baseband processor 910 (also referred to as a baseband module), radio front end module (RFEM) 915, memory 920, connectivity module 925, near field communication (NFC) controller 930, audio driver 935, camera driver 940, touch screen 945, display driver 950, sensors 955, removable memory 960, power management integrated circuit (PMIC) 965 and smart battery 970.

In some aspects, application processor 905 may include, for example, one or more CPU cores and one or more of cache memory, low drop-out voltage regulators (LDOs), interrupt controllers, serial interfaces such as serial peripheral interface (SPI), inter-integrated circuit (I2C) or universal programmable serial interface module, real time clock (RTC), timer-counters including interval and watchdog timers, general purpose input-output (IO), memory card controllers such as secure digital/multi-media card (SD/MMC) or similar, universal serial bus (USB) interfaces, mobile industry processor interface (MIPI) interfaces and Joint Test Access Group (JTAG) test access ports.

In some aspects, baseband module 910 may be implemented, for example, as a solder-down substrate including one or more integrated circuits, a single packaged integrated circuit soldered to a main circuit board, and/or a multi-chip module containing two or more integrated circuits.

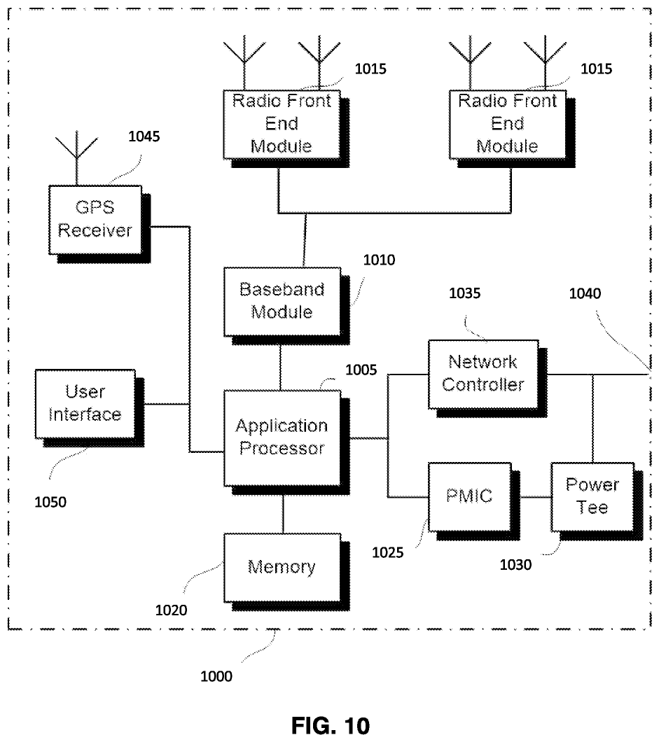

FIG. 10 illustrates a base station or infrastructure equipment radio head 1000 in which the examples disclosed herein may be implemented. For example, the examples disclosed herein may be implemented in the radio front-end module 1015, in the baseband module 1010, etc. The base station radio head 1000 may include one or more of application processor 1005, baseband modules 1010, one or more radio front end modules 1015, memory 1020, power management circuitry 1025, power tee circuitry 1030, network controller 1035, network interface connector 1040, satellite navigation receiver module 1045, and user interface 1050.

In some aspects, application processor 1005 may include one or more CPU cores and one or more of cache memory, low drop-out voltage regulators (LDOs), interrupt controllers, serial interfaces such as SPI, I2C or universal programmable serial interface module, real time clock (RTC), timer-counters including interval and watchdog timers, general purpose IO, memory card controllers such as SD/MMC or similar, USB interfaces, MIPI interfaces and Joint Test Access Group (JTAG) test access ports.

In some aspects, baseband processor 1010 may be implemented, for example, as a solder-down substrate including one or more integrated circuits, a single packaged integrated circuit soldered to a main circuit board or a multi-chip module containing two or more integrated circuits.

In some aspects, memory 1020 may include one or more of volatile memory including dynamic random access memory (DRAM) and/or synchronous dynamic random access memory (SDRAM), and nonvolatile memory (NVM) including high-speed electrically erasable memory (commonly referred to as Flash memory), phase change random access memory (PRAM), magneto resistive random access memory (MRAM) and/or a three-dimensional crosspoint memory. Memory 1020 may be implemented as one or more of solder down packaged integrated circuits, socketed memory modules and plug-in memory cards.

In some aspects, power management integrated circuitry 1025 may include one or more of voltage regulators, surge protectors, power alarm detection circuitry and one or more backup power sources such as a battery or capacitor. Power alarm detection circuitry may detect one or more of brown out (under-voltage) and surge (over-voltage) conditions.

In some aspects, power tee circuitry 1030 may provide for electrical power drawn from a network cable to provide both power supply and data connectivity to the base station radio head 1000 using a single cable.

In some aspects, network controller 1035 may provide connectivity to a network using a standard network interface protocol such as Ethernet. Network connectivity may be provided using a physical connection which is one of electrical (commonly referred to as copper interconnect), optical or wireless.

In some aspects, satellite navigation receiver module 1045 may include circuitry to receive and decode signals transmitted by one or more navigation satellite constellations such as the global positioning system (GPS), Globalnaya Navigatsionnaya Sputnikovaya Sistema (GLONASS), Galileo and/or BeiDou. The receiver 1045 may provide data to application processor 1005 which may include one or more of position data or time data. Application processor 1005 may use time data to synchronize operations with other radio base stations.

In some aspects, user interface 1050 may include one or more of physical or virtual buttons, such as a reset button, one or more indicators such as light emitting diodes (LEDs) and a display screen.

Another example is a computer program having a program code for performing at least one of the methods described herein, when the computer program is executed on a computer, a processor, or a programmable hardware component. Another example is a machine-readable storage including machine readable instructions, when executed, to implement a method or realize an apparatus as described herein. A further example is a machine-readable medium including code, when executed, to cause a machine to perform any of the methods described herein.

The examples as described herein may be summarized as follows:

An example (e.g., example 1) relates to a system configured for testing and/or determining a phase noise and/or jitter of a PLL. The system includes a first PLL configured to generate a first clock signal based on a reference clock signal, a first buffer for providing the reference clock signal to the first PLL, a mixer configured to mix the first clock signal with a second clock signal, an ADC configured to convert an output of the mixer to digital data, and a processing circuit configured to process the digital data to determine a phase noise or jitter of the first PLL and generate an output indicative of, or generated based on, the phase noise or jitter of the first PLL.

Another example, (e.g., example 2) relates to a previously described example (e.g., example 1), further comprising a second PLL configured to generate the second clock signal based on the reference clock signal, and a second buffer for providing the reference clock signal to the second PLL.

Another example, (e.g., example 3) relates to a previously described example (e.g., any one of examples 1-2), wherein the system includes more than two PLLs, each PLL being configured to generate a clock signal based on the reference clock signal, and a pair of PLLs are selected among the more than two PLLs as the first and second PLLs to determine a phase noise or jitter of the pair of PLLs.

Another example, (e.g., example 4) relates to a previously described example (e.g., any one of examples 1-3), wherein the second clock signal is received from an external clock source.

Another example, (e.g., example 5) relates to a previously described example (e.g., example 4), wherein the external clock source is a high precision clock having a phase noise or jitter below a certain threshold.

Another example, (e.g., example 6) relates to a previously described example (e.g., any one of examples 1-5), further comprising a combiner configured to combine the first clock signal and the second clock signal to generate a third clock signal.

Another example, (e.g., example 7) relates to a previously described example (e.g., any one of examples 1-6), wherein the processing circuit is configured to perform fast Fourier transform on the digital data to perform spectrum analysis on the digital data to determine the phase noise.

Another example, (e.g., example 8) relates to a previously described example (e.g., any one of examples 1-7), wherein the processing circuit is configured to integrate a phase noise power over a frequency range of interest to determine the jitter.

Another example (e.g., example 9) relates to a transceiver device. The transceiver device includes a plurality of transceiver units for transmitting and receiving data, wherein each transceiver unit includes an analog-to-digital converter and a digital-to-analog converter, a first PLL configured to generate a first clock signal based on a reference clock signal, a first buffer for providing the reference clock signal to the first PLL, a mixer configured to mix the first clock signal with a second clock signal, and a processing circuit configured to process an output of the mixer that is converted to digital domain to determine a phase noise or jitter of the first PLL and generate an output indicative of, or generated based on, the phase noise or jitter of the first PLL.

Another example, (e.g., example 10) relates to a previously described example (e.g., example 9), further including a second PLL configured to generate the second clock signal based on the reference clock signal, and a second buffer for providing the reference clock signal to the second PLL.

Another example, (e.g., example 11) relates to a previously described example (e.g., example 10), wherein the transceiver device includes more than two PLLs, each PLL being configured to generate a clock signal based on the reference clock signal, and a pair of PLLs are selected among the more than two PLLs as the first and second PLLs to determine a phase noise or jitter of the pair of PLLs.

Another example, (e.g., example 12) relates to a previously described example (e.g., any one of examples 9-11), wherein the second clock signal is received from an external clock source.

Another example, (e.g., example 13) relates to a previously described example (e.g., example 12), wherein the external clock source is a high precision clock having a phase noise or jitter below a certain threshold.

Another example, (e.g., example 14) relates to a previously described example (e.g., any one of examples 9-13), further including a combiner configured to combine the first clock signal and the second clock signal to generate a third clock signal.

Another example (e.g., example 15) relates to a method for determining a phase noise and/or jitter of a PLL. The method includes generating, by a first PLL, a first clock signal based on a reference clock signal, mixing, by a mixer, the first clock signal with a second clock signal, converting an output of the mixer to digital data, processing the digital data to determine a phase noise or jitter of the first PLL, and generating an output indicative of, or generate based on, the phase noise or jitter of the first PLL.

Another example, (e.g., example 16) relates to a previously described example (e.g., example 15), further including generating, by a second PLL, the second clock signal based on the reference clock signal.

Another example, (e.g., example 17) relates to a previously described example (e.g., example 16), wherein more than two PLLs are included in a system, each PLL being configured to generate a clock signal based on the reference clock signal, and a pair of PLLs are selected among the more than two PLLs as the first and second PLLs to determine a phase noise or jitter of the pair of PLLs.

Another example, (e.g., example 18) relates to a previously described example (e.g., any one of examples 15-17), wherein the second clock signal is received from an external clock source.

Another example, (e.g., example 19) relates to a previously described example (e.g., example 18), wherein the external clock source is a high precision clock having a phase noise or jitter below a certain threshold.

Another example, (e.g., example 20) relates to a previously described example (e.g., any one of examples 15-19), further including combining the first clock signal and the second clock signal to generate a third clock signal.

Another example, (e.g., example 21) relates to a previously described example (e.g., any one of examples 15-20), wherein fast Fourier transform is performed on the digital data to perform spectrum analysis on the digital data to determine the phase noise.

Another example, (e.g., example 22) relates to a previously described example (e.g., any one of examples 15-21), wherein a phase noise power is integrated over a frequency range of interest to determine the jitter.

Another example, (e.g., example 23) relates to a previously described example (e.g., any one of examples 15-22), wherein the conversion of the output of the mixer to digital data and/or processing the digital data to determine a phase noise or jitter of the first PLL is performed by an external testing equipment.

Another example, (e.g., example 24) relates to a non-transitory machine-readable medium including code, when executed, to cause a machine to perform the method as in any one of examples 15-23.

The aspects and features mentioned and described together with one or more of the previously detailed examples and figures, may as well be combined with one or more of the other examples in order to replace a like feature of the other example or in order to additionally introduce the feature to the other example.

Examples may further be or relate to a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. Furthermore, all examples recited herein are principally intended expressly to be only for pedagogical purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a sensor signal”, “means for generating a transmit signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software but may include digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

1. A system configured for determining a phase noise and/or jitter of a phase locked loop (PLL), comprising:
a first PLL configured to generate a first clock signal based on a reference clock signal;
a first buffer for providing the reference clock signal to the first PLL;
a mixer configured to mix the first clock signal with a second clock signal;
an analog-to-digital converter (ADC) configured to convert an output of the mixer to digital data; and
a processing circuit configured to process the digital data to determine a phase noise or jitter of the first PLL and generate an output based on the phase noise or jitter of the first PLL.

2. The system of claim 1, further comprising:
a second PLL configured to generate the second clock signal based on the reference clock signal; and
a second buffer for providing the reference clock signal to the second PLL.

3. The system of claim 1, wherein the system includes more than two PLLs, each PLL being configured to generate a clock signal based on the reference clock signal, and a pair of PLLs are selected among the more than two PLLs as the first and second PLLs to determine a phase noise or jitter of the pair of PLLs.

4. The system of claim 1, wherein the second clock signal is received from an external clock source.

5. The system of claim 4, wherein the external clock source is a high precision clock having a phase noise or jitter below a certain threshold.

6. The system of claim 1, further comprising:
a combiner configured to combine the first clock signal and the second clock signal to generate a third clock signal.

7. The system of claim 1, wherein the processing circuit is configured to perform fast Fourier transform on the digital data to perform spectrum analysis on the digital data to determine the phase noise.

8. The system of claim 1, wherein the processing circuit is configured to integrate a phase noise power over a frequency range of interest to determine the jitter.

9. A transceiver device, comprising:
a plurality of transceiver units for transmitting and receiving data, wherein each transceiver unit includes an analog-to-digital converter and a digital-to-analog converter;
a first PLL configured to generate a first clock signal based on a reference clock signal;
a first buffer for providing the reference clock signal to the first PLL;
a mixer configured to mix the first clock signal with a second clock signal; and
a processing circuit configured to process an output of the mixer that is converted to digital domain to determine a phase noise or jitter of the first PLL and generate an output based on the phase noise or jitter of the first PLL.

10. The transceiver device of claim 9, further comprising:
a second PLL configured to generate the second clock signal based on the reference clock signal; and
a second buffer for providing the reference clock signal to the second PLL.

11. The transceiver device of claim 10, wherein the transceiver device includes more than two PLLs, each PLL being configured to generate a clock signal based on the reference clock signal, and a pair of PLLs are selected among the more than two PLLs as the first and second PLLs to determine a phase noise or jitter of the pair of PLLs.

12. The transceiver device of claim 9, wherein the second clock signal is received from an external clock source.

13. The transceiver device of claim 12, wherein the external clock source is a high precision clock having a phase noise or jitter below a certain threshold.

14. The transceiver device of claim 9, further comprising:
a combiner configured to combine the first clock signal and the second clock signal to generate a third clock signal.

15. A method for determining a phase noise and/or jitter of a phase locked loop (PLL), comprising:
generating, by a first PLL, a first clock signal based on a reference clock signal;
mixing, by a mixer, the first clock signal with a second clock signal;
converting an output of the mixer to digital data;
processing the digital data to determine a phase noise or jitter of the first PLL; and
generating an output based on the phase noise or jitter of the first PLL.

16. The method of claim 15, further comprising:
generating, by a second PLL, the second clock signal based on the reference clock signal.

17. The method of claim 16, wherein more than two PLLs are included in a system, each PLL being configured to generate a clock signal based on the reference clock signal, and a pair of PLLs are selected among the more than two PLLs as the first and second PLLs to determine a phase noise or jitter of the pair of PLLs.

18. The method of claim 15, wherein the second clock signal is received from an external clock source.

19. The method of claim 18, wherein the external clock source is a high precision clock having a phase noise or jitter below a certain threshold.

20. The method of claim 15, further comprising:
combining the first clock signal and the second clock signal to generate a third clock signal.

21. The method of claim 15, wherein fast Fourier transform is performed on the digital data to perform spectrum analysis on the digital data to determine the phase noise.

22. The method of claim 15, wherein a phase noise power is integrated over a frequency range of interest to determine the jitter.

23. The method of claim 15, wherein the conversion of the output of the mixer to digital data and/or processing the digital data to determine a phase noise or jitter of the first PLL is performed by an external testing equipment.

24. A non-transitory machine-readable medium including code, when executed, to cause a machine to perform the method of claim 15.
